(19) United States
(12) Patent Application Publication
(10) Pub. No.: US 2026/0353765 A1
(43) Pub. Date: Nov. 5, 2026

(54) SEMICONDUCTOR DEVICE AND METHODS OF FORMING THE SAME

(71) Applicant: Taiwan Semiconductor Manufacturing Co., Ltd., Hsinchu (TW)

(72) Inventors: Cheng-I Lin, Hsinchu (TW); Cheng-Wei Chang, Hsinchu (TW); Ting-Hsiang Chang, New Taipei City (TW); Chih-Tang Peng, Zhubei City (TW); Yung-Cheng Lu, Hsinchu (TW)

(21) Appl. No.: 19/741,441

(22) Filed: Jul. 14, 2026

Related U.S. Application Data
(63) Continuation of application No. 18/152,557, filed on Jan. 10, 2023.
(60) Provisional application No. 63/385,649, filed on Dec. 1, 2022.

(51) Int. Cl. H10D 84/03; H10D 84/01; H10D 84/85; H10W 10/00; H10W 10/17

(52) U.S. Cl. CPC H10D 84/038; H10D 84/0188; H10D 84/0193; H10D 84/853; H10W 10/014; H10W 10/17

(57) ABSTRACT

In an embodiment, a method includes: forming a first fin and a second fin over a semiconductor substrate; forming an isolation region between the first fin and the second fin, forming the isolation region comprising: depositing an oxide liner along the first fin, the second fin, and the semiconductor substrate, the oxide liner comprising a first upper portion and a first lower portion along the first fin, the first lower portion being between the first upper portion and the semiconductor substrate; thinning the oxide liner; depositing an insulation material over the oxide liner; and recessing the insulation material; and forming a gate structure over the first fin, the second fin, and the isolation region.

### PRIORITY CLAIM AND CROSS-REFERENCE

This application is a continuation of U.S. Patent Application No. 18/152,557, filed Jan. 10, 2023, which claims the benefit of U.S. Provisional Application No. 63/385,649, filed Dec. 1, 2022, which applications are hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a FinFET in a three-dimensional view, in accordance with some embodiments.

FIGS. 2, 3A, 3B, 4A, 4C, 5A, 5C, 6, 7, 8A, 8B, 9, 10A, 10B, 11A, 11B, 12A, 12B, 12C, 12D, 13A, 13B, 14A, 14B, 15A, 15B, 16A, 16B, 16C, 17A, 17B, 18A, and 18B are cross-sectional views of intermediate stages in the manufacturing of FinFETs, in accordance with some embodiments.

FIGS. 4B and 5B are diagrams of intermediate processes in the manufacturing of FinFETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments described herein provide the formation of semiconductor devices, including fin field effect transistors (FinFETs). In particular, isolation regions are formed between neighboring semiconductor fins such that deposition of the insulation fill material is deposited free of voids. For example, an oxide liner may be formed over the semiconductor fins and within recesses between the semiconductor fins. Portions of the oxide liner at upper regions of the semiconductor fins may overhang into the recess, which could obstruct deposition of subsequent materials into the recesses. A post-deposition treatment may be performed to thin and reshape the oxide liner to a sufficient degree that a subsequently formed insulation fill material may be deposited to fill remainders of the recesses with fewer voids or being free of voids. The embodiments result in semiconductor devices being fabricated with higher yield and greater efficiency, thereby reducing fabrication costs. The embodiments described, however, are intended to be illustrative and are not intended to be limiting, as the ideas presented herein may be applied in a wide variety of embodiments. For example, methods described herein may be applied to depositions of other pre-layer (e.g., liner) and gap-fill materials in recesses having high aspect ratios throughout the fabrication of a semiconductor device.

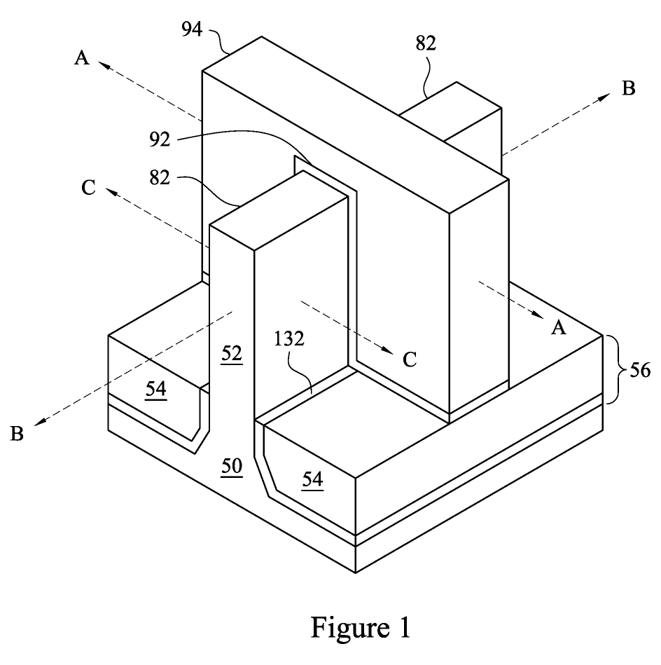

FIG. 1 illustrates an example of a FinFET in a three-dimensional view, in accordance with some embodiments. The FinFET comprises a fin 52 (e.g., a semiconductor fin) on a substrate 50 (e.g., a semiconductor substrate). Isolation regions 56 are disposed in the substrate 50, and the fin 52 protrudes above and from between neighboring isolation regions 56. The isolation regions 56 may include a plurality of dielectric layers, such as an oxide liner 132, an insulation material 54, and one or more other layers (not specifically illustrated). Although the isolation regions 56 are described/illustrated as being separate from the substrate 50, as used herein the term “substrate” may be used to refer to just the semiconductor substrate or a semiconductor substrate inclusive of isolation regions. Additionally, although the fin 52 is illustrated as a single, continuous material as the substrate 50, the fin 52 and/or the substrate 50 may comprise a single material or a plurality of materials. In this context, the fin 52 refers to the portion extending between the neighboring isolation regions 56.

A gate dielectric layer 92 is along sidewalls and over a top surface of the fin 52, and a gate electrode 94 is over the gate dielectric layer 92. Source/drain regions 82 are disposed in opposite sides of the fin 52 with respect to the gate dielectric layer 92 and gate electrode 94. Source/drain region(s) 82 may refer to a source or a drain, individually or collectively dependent upon the context. FIG. 1 further illustrates reference cross-sections that are used in later figures. Cross-section A-A is along a longitudinal axis of the gate electrode 94 and in a direction, for example, perpendicular to the direction of current flow between the source/drain regions 82 of the FinFET. Cross-section B-B is perpendicular to cross-section A-A and is along a longitudinal axis of the fin 52 and in a direction of, for example, a current flow between the source/drain regions 82 of the FinFET. Cross-section C-C is parallel to cross-section A-A and extends through a source/drain region of the FinFET. Subsequent figures refer to these reference cross-sections for clarity.

Some embodiments discussed herein are discussed in the context of FinFETs formed using a gate-last process. In other embodiments, a gate-first process may be used. Also, some embodiments contemplate aspects used in planar devices, such as planar FETs, nanostructure (e.g., nanosheet, nanowire, gate-all-around, or the like) field effect transistors (NSFETs), or the like.

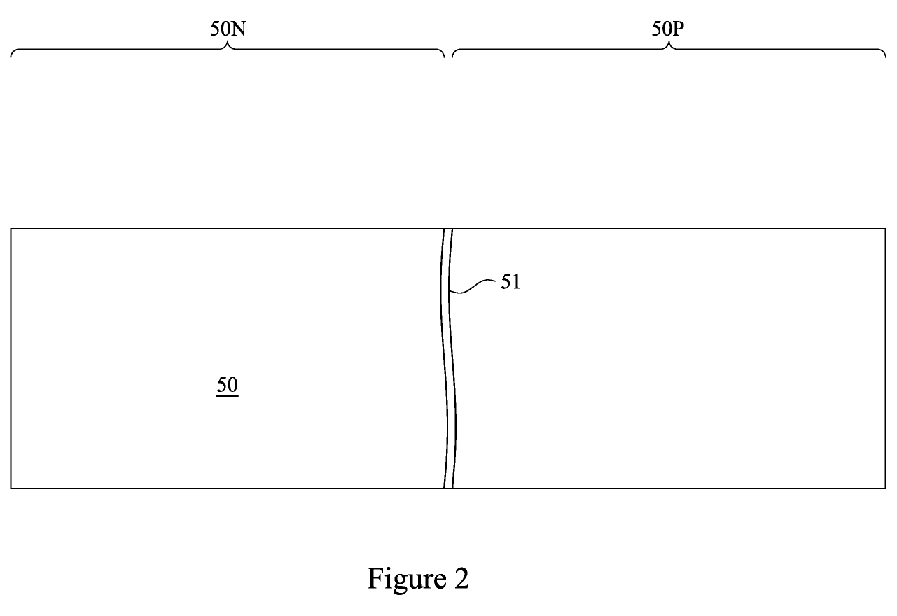

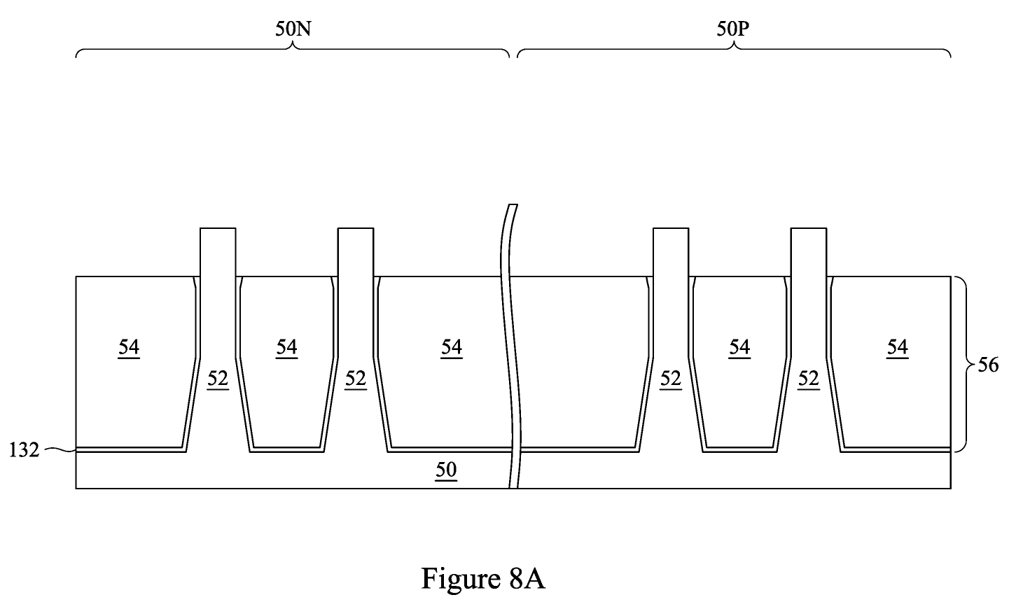

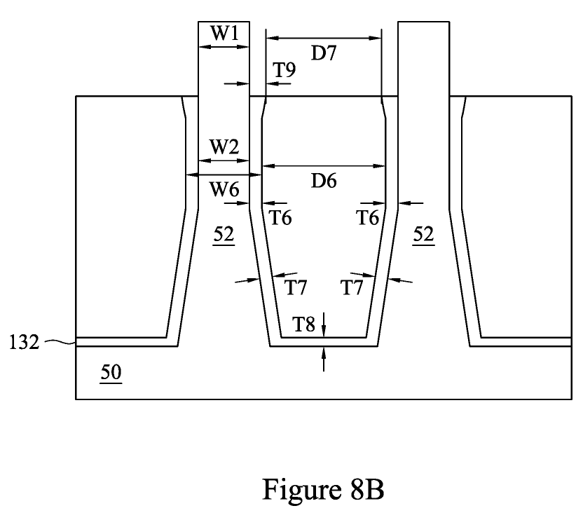

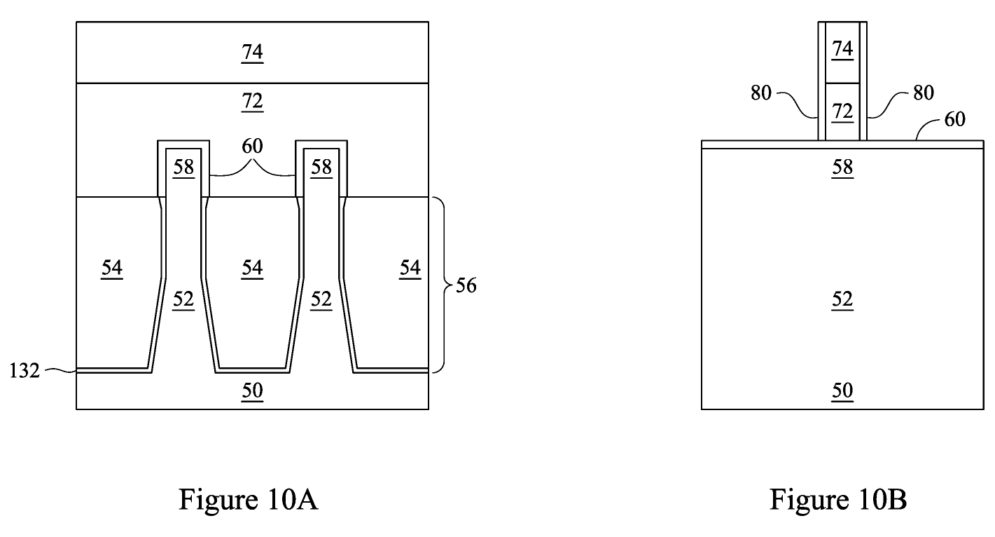

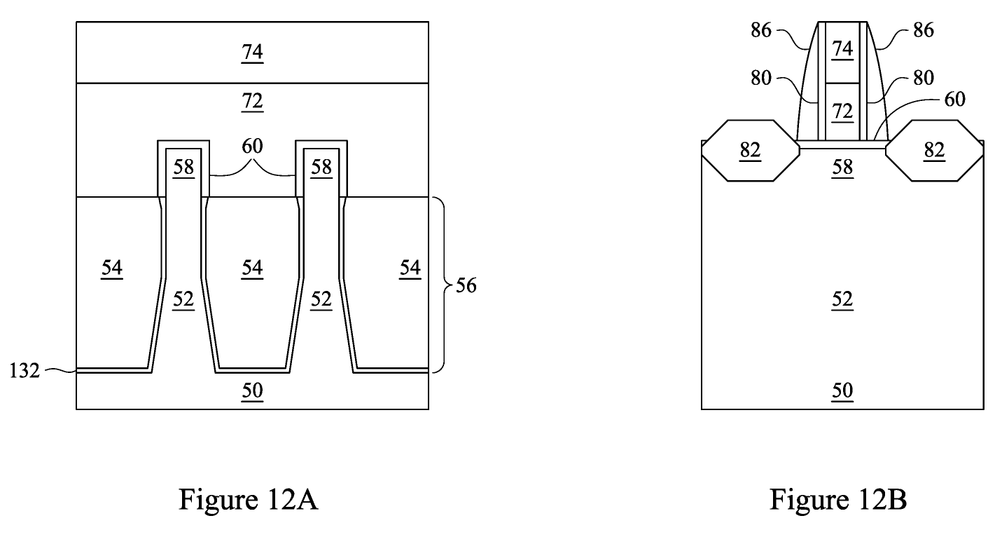

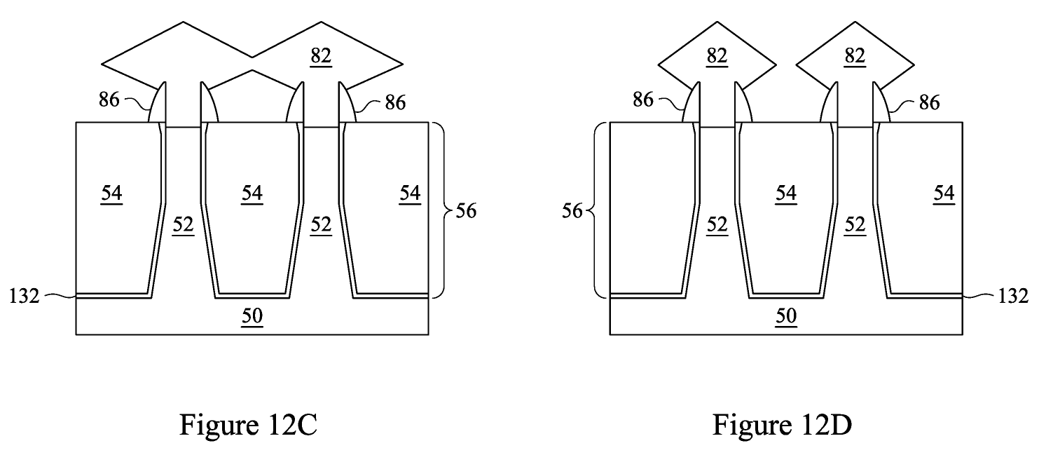

FIGS. 2 through 18B include cross-sectional views of intermediate stages in the manufacturing of FinFETs, in accordance with some embodiments. FIGS. 2, 3A, 3B, 4A, 4C, 5A, 5C, 6, 7, 8A, 9 illustrate reference cross-section A-A illustrated in FIG. 1, except for multiple fin/FinFets FIGS. 10A, 8B, 11A, 12A, 13A, 14A, 15A, 16A, 17A, and 18A are illustrated along reference cross-section A-A illustrated in FIG. 1, and FIGS. 10B, 11B, 12B, 13B, 14B, 15B, 16B, 16C, 17B, and 18B are illustrated along a similar cross-section B-B illustrated in FIG. 1, except for multiple fins/FinFETs. FIGS. 12C and 12D are illustrated along reference cross-section C-C illustrated in FIG. 1, except for multiple fins/FinFETs.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type FinFETs. The p-type region 50P can be for forming p-type devices, such as PMOS transistors, e.g., p-type FinFETs. The n-type region 50N may be physically separated from the p-type region 50P (as illustrated by divider 51), and any number of device features (e.g., other active devices, doped regions, isolation structures, etc.) may be disposed between the n-type region 50N and the p-type region 50P.

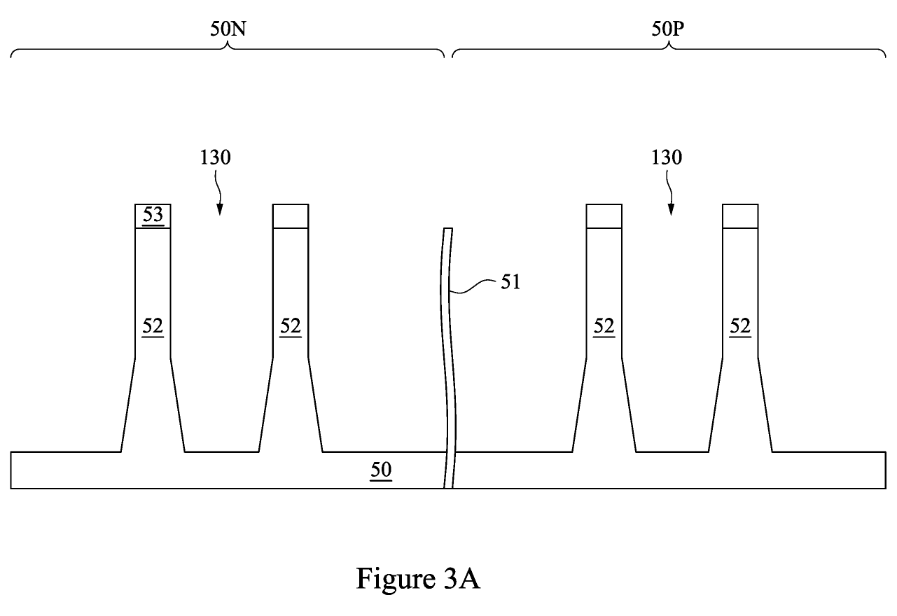

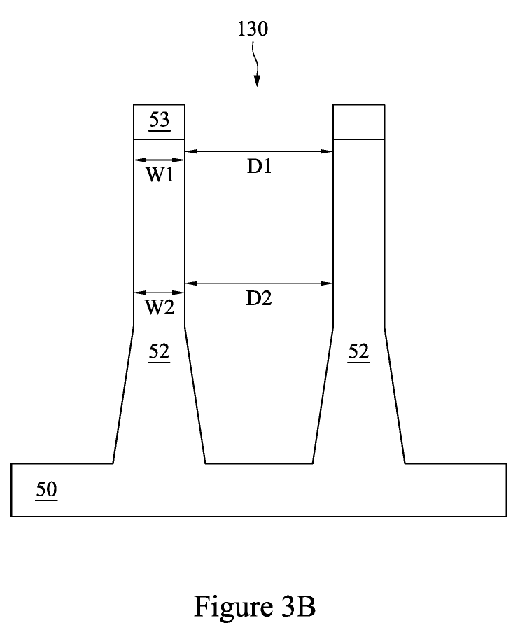

In FIGS. 3A-3B, fins 52 are formed in the substrate 50. The fins 52 are semiconductor strips. In some embodiments, the fins 52 may be formed in the substrate 50 by etching trenches in the substrate 50. The etching may be any acceptable etch process, such as a reactive ion etch (RIE), neutral beam etch (NBE), the like, or a combination thereof. The etch may be anisotropic.

The fins may be patterned by any suitable method. For example, the fins 52 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Masks 53 (e.g., spacers) are formed alongside the patterned sacrificial layer using a self-aligned process. The sacrificial layer is then removed, and the remaining masks 53 may then be used to pattern the fins. In some embodiments, the masks 53 (or other layer) may remain on the fins 52. After formation, neighboring fins 52 may be separated from one another by recesses 130.

Referring to FIG. 3B, a zoomed-in view of a pair of neighboring fins 52 (e.g., from either the n-type region 50N or the p-type region 50P) is illustrated. Upper regions of the fins 52 may have widths W₁ (e.g., diameters measured parallel to a major surface of the substrate 50) and be separated from one another by a lateral distance D₁ (e.g., a shortest lateral distance). In addition, middle regions of the fins 52 may have widths W₂ (e.g., diameters) and be separated from one another by a lateral distance D₂. In some embodiments, each of the widths W₂ may be the same or less than the width W₁. In addition, the lateral distance D₂ may be the same or greater than the lateral distance D₁.

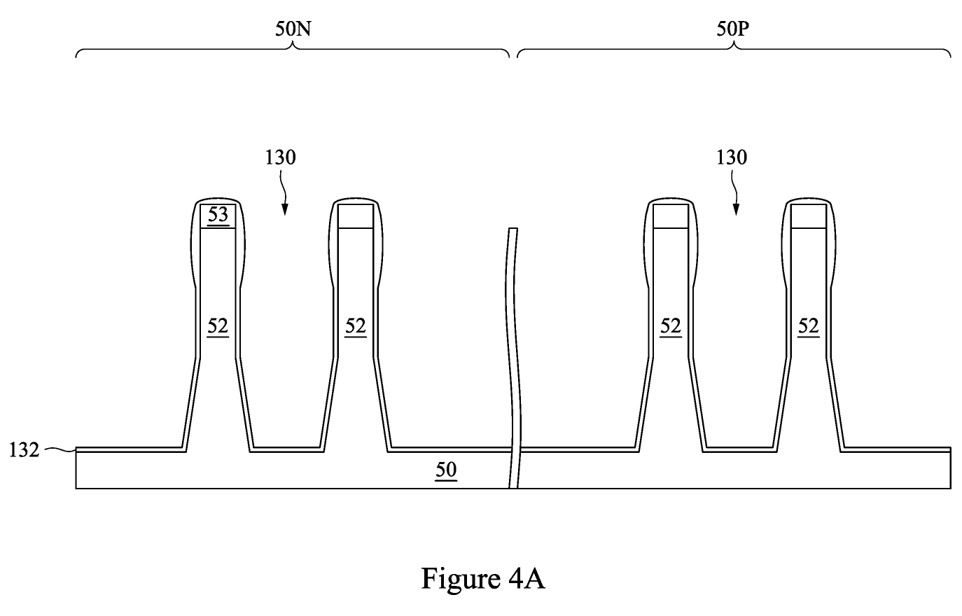

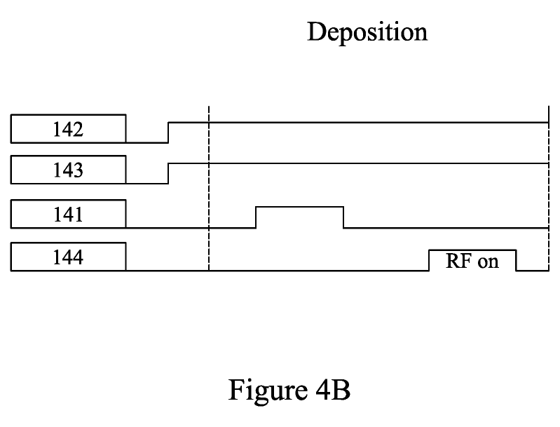

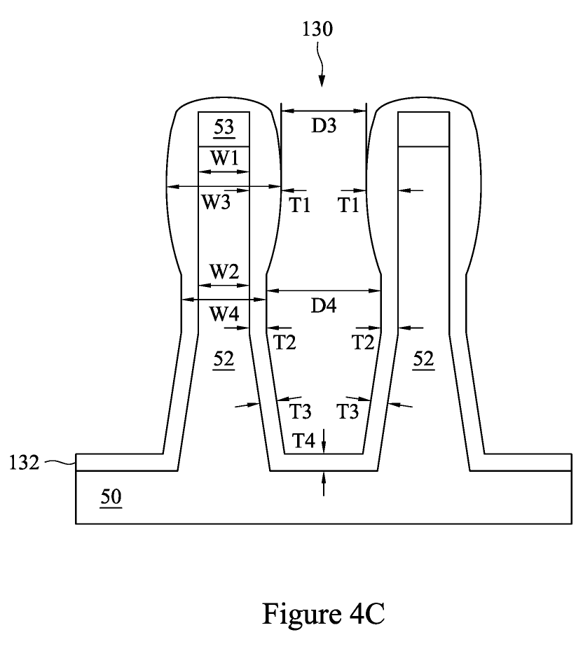

In FIGS. 4A-4C, an oxide liner 132 is formed in the recesses 130 over the substrate 50 and along the fins 52. The oxide liner 132 may also be formed over and around the masks 53. In accordance with some embodiments, the oxide liner 132 may be silicon oxide, silicon oxynitride, or the like, and be conformally deposited by, for example, atomic layer deposition (ALD), chemical vapor deposition (CVD), combinations thereof, the like, or a suitable process.

Referring to FIG. 4B, in some embodiments, the oxide liner 132 may be formed by ALD and utilize a first precursor 141, a second precursor 142, an ambient material 143, and a plasma generator 144. Each of the precursors 141, 142 and the ambient material 143 may be stored in a gas or liquid supply, which may be a supply vessel, such as a gas or liquid storage tank, that is located either locally to a reaction chamber or else may be located remotely from the reaction chamber. In some embodiments (not specifically illustrated), the supply vessels (or remote storage) may be connected to a flow controller by supply lines, and the flow controller may be connected to the reaction chamber by a manifold.

For example, the second precursor 142 may be an oxygen precursor 142 and may be oxygen (O₂), carbon dioxide (CO₂), a combination thereof, or the like, the first precursor 141 may be a silicon precursor 141 and may be a silane with or without various attached groups, such as SiH₄, SAM24, combinations thereof, or the like. In addition, the ambient material 143 may be argon, helium, other inert gases, a combination thereof, or the like. In some embodiments, the ambient material 143 (e.g., argon) and the oxygen precursor 142 (e.g., O₂) may be flowed into the reaction chamber (not specifically illustrated) throughout the ALD process. Each cycle of the ALD process may include sub-cycles alternating between depositions of silicon and oxygen. For example, a first sub-cycle may include flowing the silicon precursor 141 (e.g., SAM24) into the reaction chamber for a period of time to deposit silicon-containing molecules onto the structure (e.g., attached by chemical bonds), and a second sub-cycle of each ALD cycle may include temporarily turning on the plasma generator 144 to deposit oxygen or oxygen-containing molecules onto the structure (e.g., attached to the deposited silicon by chemical bonds).

In some embodiments, the flow rate of the oxygen precursor 142 may be constant and the flow rate of the ambient material 143 may also be constant. In addition, one or both of those flow rates may be adjusted throughout the ALD cycles to maintain a constant or controlled total pressure, such as ranging from 2 torr to 6 torr, or desired partial pressures of the various materials within the reaction chamber. In addition, the plasma generator 144 may be turned on with a radio frequency (RF) power being less than or equal to 400 Watts (W), such as ranging from 165 W to 600 W. The ALD process to form the oxide liner 132 may be performed at a temperature ranging from 75 °C to 390 °C. However, any suitable process conditions may be utilized. A desired number of cycles may be performed to form the oxide liner 132 with an average thickness ranging from 15 Å to 30 Å, such as 20 Å.

Referring to FIG. 4C, a zoomed-in view of the pair of neighboring fins 52 (see FIG. 3B) is illustrated. In some embodiments, the thickness of the oxide liner 132 may vary over the structure, for example, due to deposition over the contours of the fins 52 and the substrate 50. As illustrated, the oxide liner 132 along the upper regions of the fins 52 may have a thickness T₁, which may be greater than a thickness T₂ of the oxide liner 132 along the middle regions of the fins 52. In addition, the thickness T₁ may also be greater than a thickness T₃ of the oxide liner 132 along a lower region of the fins 52 and/or greater than a thickness T₄ of the oxide liner 132 along the substrate 50. Further, each of the thicknesses T₃, T₄ (e.g., along the lower region of the fins 52 and the substrate 50, respectively) may be greater than the thickness T₂ (e.g., along the middle region of the fins 52). For example, each of the thicknesses T₁, T₄ may be the same or greater than the average thickness (e.g., 20 Å) of the oxide liner 132 discussed above, and each of the thicknesses T₂, T₃ may be the same as the average thickness of the oxide liner 132.

As illustrated, in some embodiments, after forming the oxide liner 132, neighboring fins 52 may remain separated from each other by the recesses 130. In addition, a combined fin may be referred to as the combination of a fin 52 including an adjacent respective portion of the oxide liner 132. A width W₃ of an upper region of the combined fin is calculated as the width W₁ plus two times the thickness T₁, and a width W₄ of a middle region of the combined fin is calculated as the width W₂ plus two times the thickness T₂. Further, the upper regions of the neighboring combined fins may be separated from one another by a lateral distance D₃, and the middle regions of the neighboring combined fins may be separated by a lateral distance D₄. The width W₃ may be greater than the width W₄ either or both of the following reasons: (A) the thickness T₁ of the oxide liner 132 may be greater than the thickness T₂ of the oxide liner, and/or (B) the width W₁ of the upper region of the fin 52 may be greater than the width W₂ of the middle region of the fin 52. As a result, the lateral distance D₄ between the middle regions of the combined fins may be greater than the lateral distance D₃ between the upper regions of the combined fins to shape a remainder of the recess 130 into a cove or a tear drop shape. For example, the lateral distance D₃ may be less than 2 nm, such as less than 2 nm, or range from 1 nm to 3 nm.

Moreover, the shapes of the fins 52 and the varying thicknesses of the oxide liner 132 may result in overhang of the oxide liner 132 into the recess 130. For example, an upper portion of the oxide liner 132 along the upper region of the fins 52 may overhang as compared to other portions of the oxide liner 132 below the upper portion, such as a middle portion of the oxide liner 132 along the middle region of the fins 52. In some embodiments, the upper portion of the oxide liner 132 may extend along an upper 25 nm of the fin 52 (e.g., an upper 15% to 20% of the fin 52 and the mask 53, if present), and the middle portion of the oxide liner 132 may be along the middle region of the fin 52 at 60 nm to 80 nm from a top of the fin 52 (e.g., 40% to 55% from the top of the fin 52 and the mask 53, if present). In some embodiments, the upper portion of the oxide liner 132 may overhang by a distance ranging from 4 Å to 6 Å, such as 5 Å.

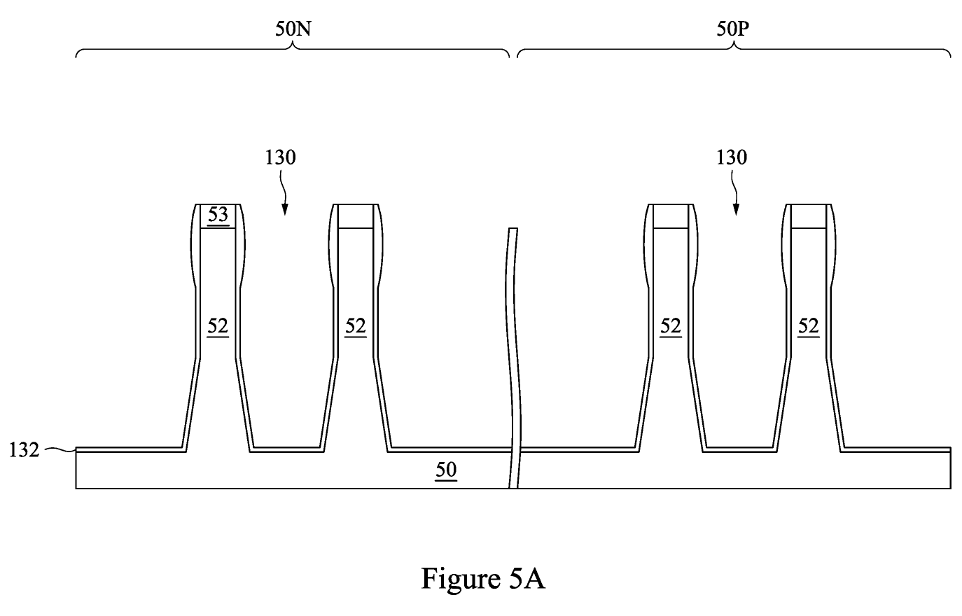

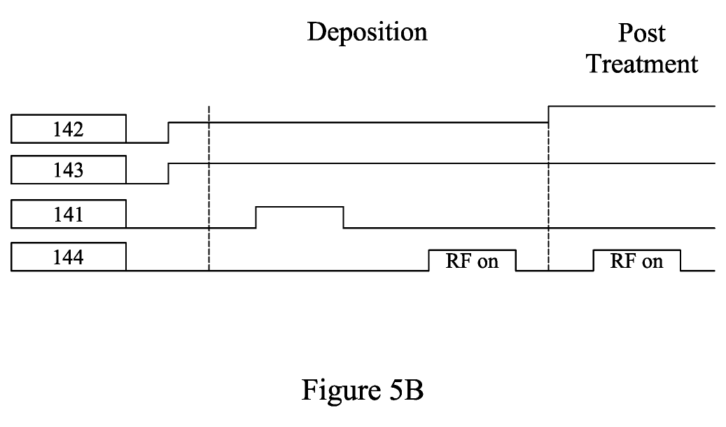

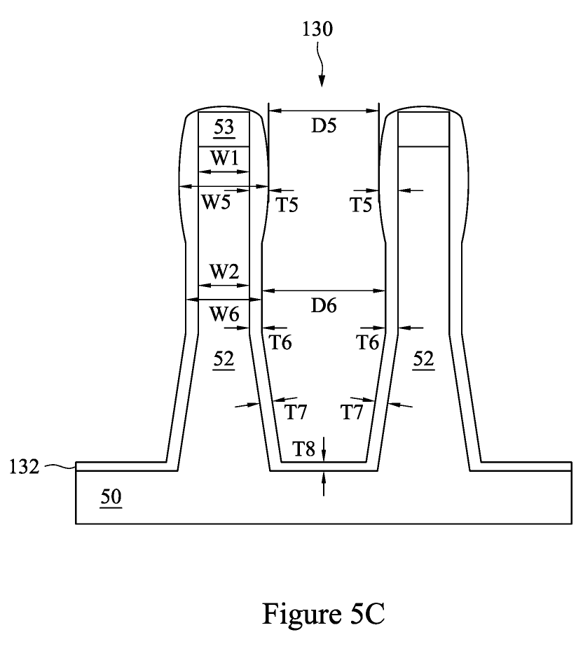

In FIGS. 5A-5C, a post-deposition treatment is performed on the oxide liner 132, in accordance with some embodiments. The post-deposition treatment may be a continuation of the ALD process forming the oxide liner 132, such as a post-ALD sub-cycle performed within the reaction chamber after deposition of the oxide liner 132. In some embodiments, the post-deposition treatment etches the oxide liner 132 (e.g., an anisotropic etch) using plasmas of certain ones of the deposition precursors (e.g., the oxygen precursor 142 and/or the ambient material 143). In addition, the post-deposition treatment may reshape and/or thin certain portions of the oxide liner 132 in order to improve one or more depositions of subsequent layers. For example, the upper portions of the oxide liner 132 may be etched by greater amounts than other portions of the oxide liner 132 in order to widen the mouth of the recess 130. Further, the post-deposition treatment improves robustness of the structure and protection of the fins 52 by removing impurities (e.g., nitrogen and/or carbon) and densifying the oxide liner 132. In some embodiments, the mouths of the recesses 130 between neighboring combined fins (e.g., the fins 52 and portions of the oxide liner 132) may be widened by mostly thinning the oxide liner 132 along sidewalls of the fins 52, such as along the upper regions of the fins 52 (e.g., at or proximal to the masks 53). Optionally, an anneal process may be performed on the oxide liner 132 at the end of the post-deposition treatment. Following the post-deposition treatment, the oxide liner 132 may have an average thickness ranging from 18 Å to 20 Å.

Referring to FIG. 5B, the post-deposition treatment of the oxide liner 132 may be performed by maintaining flow rates of the oxygen precursor 142 (e.g., O₂) and the ambient material 143 (e.g., argon) into the reaction chamber and turning on the plasma generator 144. In some embodiments, each of the flow rates of the oxygen precursor 142 and the ambient material 143 may remain the same or be increased to 150% to 200% of the respective deposition flow rate, such as increasing to 200% of the respective deposition flow rate. For example, as illustrated, the treatment flow rate of the oxygen precursor 142 may increase to 200% of its deposition flow rate, and the treatment flow rate of the ambient material 143 may remain the same as its deposition flow rate. In addition, the plasma generator 144 may be turned on with an RF power ranging from 165 W to 600 W, such as 400 W or greater. In some embodiments, the treatment RF power may be greater than or equal to 11 times the deposition RF power, such as being 25 times the deposition RF power. Further, the post-deposition treatment may be performed at a constant or controlled total pressure, such as ranging from 2 torr to 6 torr, and at temperatures ranging from 75 °C to 390 °C.

Referring to FIG. 5C, a zoomed-in view of the pair of neighboring fins 52 (see FIGS. 3B and 4C) is illustrated. As discussed above, the post-deposition treatment may etch the upper portions of the oxide liner 132 (e.g., along the upper regions of the fins 52) and portions of the oxide liner 132 along the substrate 50 at faster rates, while middle and lower portions of the oxide liner 132 along the middle and lower regions of the fins 52 may be etched at slower rates. As a result, the post-deposition treatment decreases the thickness of the oxide liner 132 by varying amounts at different locations, for example, due to the oxide liner 132 being disposed along the contours of the fins 52 and the substrate 50.

For example, after performing the post-deposition treatment, the upper portion of the oxide liner 132 may have a thickness T₅, which may be greater than a thickness T₆ of the middle portion of the oxide liner 132. In addition, the thickness T₅ may also be greater than a thickness T₇ of a lower portion of the oxide liner 132 along the lower region of the fins 52 and greater than a thickness T₈ of the oxide liner 132 along the substrate 50. Further, each of the thicknesses T₆, T₇ (e.g., along the middle and lower regions of the fins 52, respectively) may be greater than the thickness T₈ (e.g., along the substrate 50). As a result, after the post-deposition treatment, the upper regions of the neighboring combined fins (e.g., the fins 52 and the oxide liner 132) may be separated from one another by a lateral distance D₅ (e.g., greater than the lateral distance D₃ before the post-deposition treatment) ranging from 1 nm to 3 nm, such as being greater than 2 nm.

In addition, after the post-deposition treatment, the combined fin (e.g., the fin 52 and portion of the oxide liner 132) has a width W₅ in the upper region and a width W₆ in the middle region. The width W₅ of the upper region is calculated as the width W₁ of the upper region of the fin 52 plus two times the thickness T₅, and the width W₆ of the middle region is calculated as the width W₂ of the middle region of the fin 52 plus two times the thickness T₆. Further, the upper regions of the neighboring combined fins may be separated from one another by a lateral distance D₅, and the middle regions of the neighboring combined fins may be separated by a lateral distance D₆. The width W₅ may be the same as the width W₆ or greater than the width W₆ albeit by a lesser degree than the width W₃ is greater than the width W₄ (e.g., before the post-deposition treatment). As a result, the lateral distance D₆ between the middle regions of the combined fins may be the same or greater than the lateral distance D₅ between the upper regions of the combined fins. For example, the lateral distance D₅ may be greater than 2 nm, such as greater than or equal to 2 nm, or range from 1 nm to 3 nm. The middle regions of the neighboring combined fins are separated from one another by a lateral distance D₆, which may be greater than the lateral distance D₄ (e.g., before the post-deposition treatment). In addition, the lateral distance D₆ may be the same or greater than the lateral distance D₅. Further, the increase of the lateral distances D₃ to D₅ between the upper regions may be greater than the increase of the lateral distances D₄ to D₆ between the middle regions.

Moreover, the post-deposition treatment results in a decrease in the overhang of the upper portion of the oxide liner 132 as compared to the other portions of the oxide liner 132 (e.g., below the upper portion, such as the middle portion). For example, the upper portion of the oxide liner 132 may be etched such that the thickness T₅ ranges from 80% to 90% of the thickness T₁ (e.g., before the post-deposition treatment), such that the thickness T₆ ranges from 90% to 100% of the thickness T₂, such that the thickness T₇ ranges from 85% to 95% of the thickness T₃, and such that the thickness T₈ ranges from 60% to 80% of the thickness T₄. In addition, the overhang of the upper portion of the oxide liner 132 compared to the middle portion of the oxide liner 132 may decrease to a distance ranging from 0.8 Å to 2.3 Å, such as decreasing to 15% to 45% of the overhang before performing the post-deposition treatment.

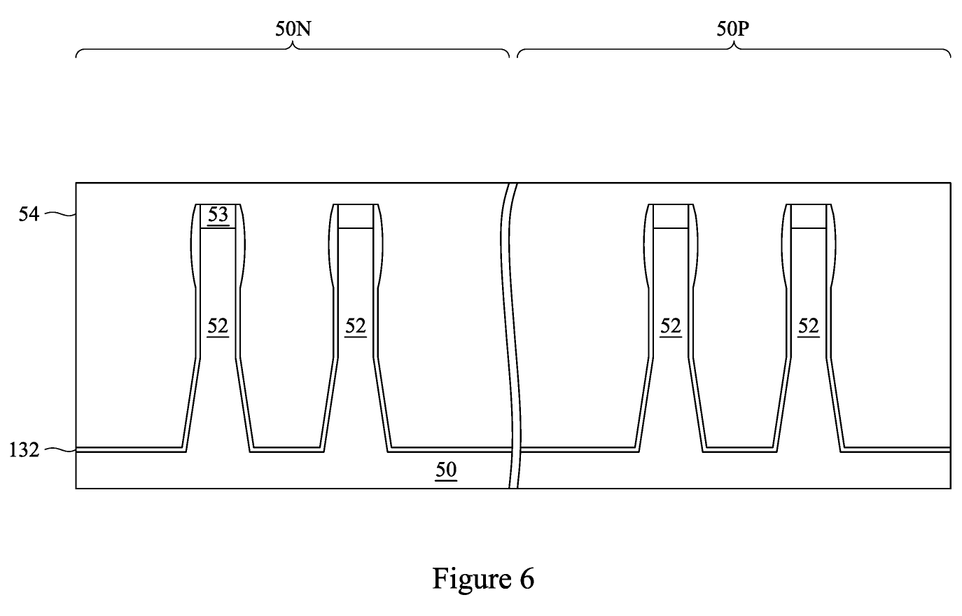

In FIG. 6, an insulation material 54 is formed over the substrate 50 and between neighboring fins 52. The insulation material 54 may be an oxide, such as silicon oxide, a nitride, the like, or a combination thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material 54 is silicon oxide formed by a FCVD process. An anneal process may be performed once the insulation material is formed. In an embodiment, the insulation material 54 is formed such that excess insulation material 54 covers the fins 52. Although the insulation material 54 is illustrated as a single layer, some embodiments may utilize multiple layers. For example, in some embodiments an initial liner (not shown) may first be formed along a surface of the oxide liner 132. Thereafter, a fill material, such as those discussed above may be formed over the initial liner to form the insulation material 54.

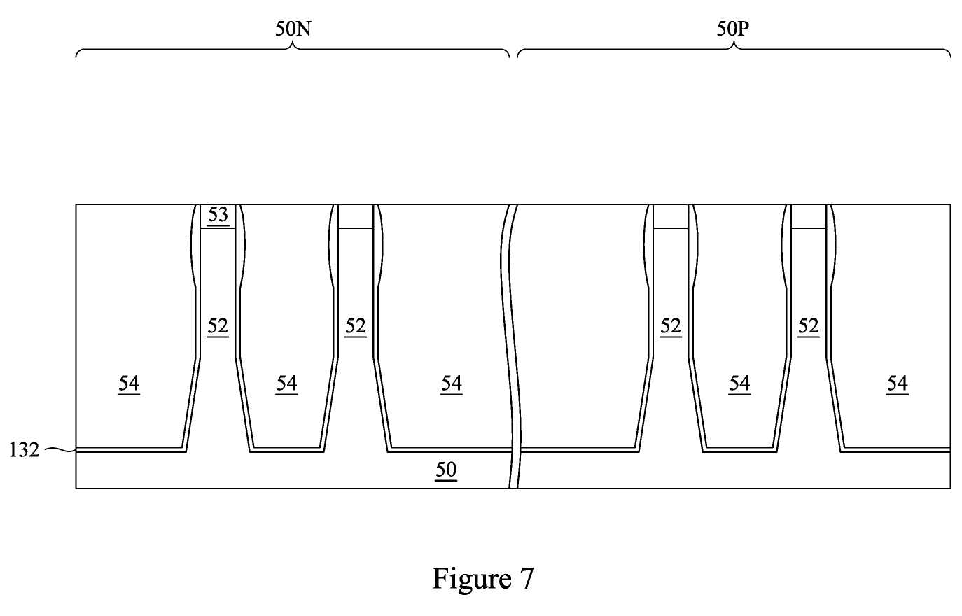

In FIG. 7, a removal process is applied to the insulation material 54 to remove excess insulation material 54 over the fins 52. In some embodiments, a planarization process such as a chemical mechanical polish (CMP), an etch-back process, combinations thereof, or the like may be utilized. The planarization process exposes the fins 52 such that top surfaces of the fins 52 and the insulation material 54 are level after the planarization process is complete. In embodiments in which a mask 53 remains on the fins 52, the planarization process may expose the mask 53 (as illustrated) or remove the mask such that top surfaces of the mask 53 or the fins 52, respectively, and the insulation material 54 are level after the planarization process is complete.

In FIGS. 8A and 8B, the insulation material 54 and the oxide liner 132 are recessed to form Shallow Trench Isolation (STI) regions 56 (e.g., isolation regions). The insulation material 54 and the oxide liner 132 are recessed such that upper portions of fins 52 in the n-type region 50N and in the p-type region 50P protrude from between neighboring STI regions 56. Further, the top surfaces of the STI regions 56 may have a flat surface as illustrated, a convex surface, a concave surface (such as dishing), or a combination thereof. The top surfaces of the STI regions 56 may be formed flat, convex, and/or concave by an appropriate etch. The STI regions 56 may be recessed using an acceptable etching process, such as one that is selective to the materials of the insulation material 54 and the oxide liner 132 (e.g., etches the material of the insulation material 54 at a faster rate than the material of the masks 53 and/or the fins 52). For example, an oxide removal using, for example, dilute hydrofluoric (dHF) acid may be used. In some embodiments, the insulation material 54 and the oxide liner 132 are recessed using an anisotropic dry etch process, wherein the masks 53 (if present) protect the fins 52 from being etched. The masks 53 may be removed by the etch process or subsequently removed by a suitable process.

Referring to FIG. 8B, a zoomed-in view of the pair of neighboring fins 52 (see FIGS. 3B, 4C, and 5C) is illustrated. In some embodiments, after recessing the insulation material 54 and the oxide liner 132, a part of the upper region of the fins 52 may remain covered by a part of the upper portion of the oxide liner 132. As a result, the remaining upper portion of the oxide liner 132 may have a thickness T₉ less than the thickness T₅ and greater than the thickness T₆ of the middle portion of the oxide liner 132.

The process described with respect to FIGS. 2 through 6 is just one example of how the fins 52 may be formed. In some embodiments, the fins may be formed by an epitaxial growth process. For example, a dielectric layer can be formed over a top surface of the substrate 50, and trenches can be etched through the dielectric layer to expose the underlying substrate 50. Homoepitaxial structures can be epitaxially grown in the trenches, and the dielectric layer can be recessed such that the homoepitaxial structures protrude from the dielectric layer to form fins. Additionally, in some embodiments, heteroepitaxial structures can be used for the fins 52. For example, the fins 52 in FIG. 5A can be recessed, and a material different from the fins 52 may be epitaxially grown over the recessed fins 52. In such embodiments, the fins 52 comprise the recessed material as well as the epitaxially grown material disposed over the recessed material. In an even further embodiment, a dielectric layer can be formed over a top surface of the substrate 50, and trenches can be etched through the dielectric layer. Heteroepitaxial structures can then be epitaxially grown in the trenches using a material different from the substrate 50, and the dielectric layer can be recessed such that the heteroepitaxial structures protrude from the dielectric layer to form the fins 52. In some embodiments where homoepitaxial or heteroepitaxial structures are epitaxially grown, the epitaxially grown materials may be in situ doped during growth, which may obviate prior and subsequent implantations although in situ and implantation doping may be used together.

Still further, it may be advantageous to epitaxially grow a material in n-type region 50N (e.g., an NMOS region) different from the material in p-type region 50P (e.g., a PMOS region). In various embodiments, upper portions of the fins 52 may be formed from silicon-germanium (SiₓGe₁₋ₓ, where x can be in the range of 0 to 1), silicon carbide, pure or substantially pure germanium, a III-V compound semiconductor, a II-VI compound semiconductor, or the like. For example, the available materials for forming III-V compound semiconductor include, but are not limited to, indium arsenide, aluminum arsenide, gallium arsenide, indium phosphide, gallium nitride, indium gallium arsenide, indium aluminum arsenide, gallium antimonide, aluminum antimonide, aluminum phosphide, gallium phosphide, and the like.

Further in FIGS. 8A and 8B, appropriate wells (not shown) may be formed in the fins 52 and/or the substrate 50. In some embodiments, a P well may be formed in the n-type region 50N, and an N well may be formed in the p-type region 50P. In some embodiments, a P well or an N well are formed in both the n-type region 50N and the p-type region 50P.

In the embodiments with different well types, the different implant steps for the n-type region 50N and the p-type region 50P may be achieved using a photoresist and/or other masks (not shown). For example, a photoresist may be formed over the fins 52 and the STI regions 56 in the n-type region 50N. The photoresist is patterned to expose the p-type region 50P of the substrate 50. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration of equal to or less than 10¹⁸ cm⁻³, such as between about 10¹⁶ cm⁻³ and about 10¹⁸ cm⁻³. After the implant, the photoresist is removed, such as by an acceptable ashing process.

Following the implanting of the p-type region 50P, a photoresist is formed over the fins 52 and the STI regions 56 in the p-type region 50P. The photoresist is patterned to expose the n-type region 50N of the substrate 50. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration of equal to or less than 10¹⁸ cm⁻³, such as between about 10¹⁶ cm⁻³ and about 10¹⁸ cm⁻³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

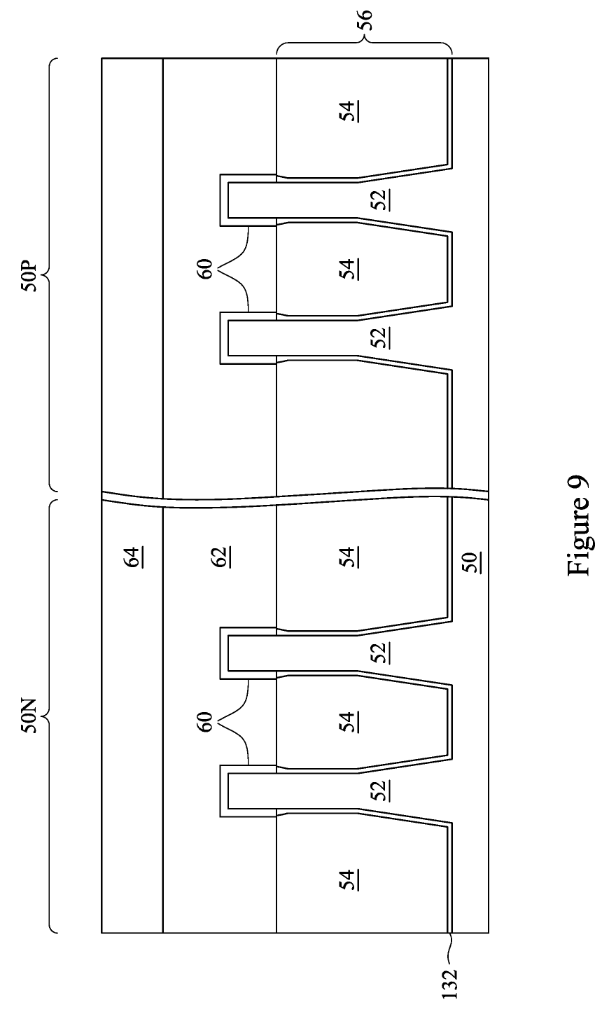

In FIG. 9, a dummy dielectric layer 60 (e.g., a dummy gate dielectric) is formed on the fins 52. The dummy dielectric layer 60 may be, for example, silicon oxide, silicon nitride, a combination thereof, or the like, and may be deposited or thermally grown according to acceptable techniques. A dummy gate layer 62 is formed over the dummy dielectric layer 60, and a mask layer 64 is formed over the dummy gate layer 62. The dummy gate layer 62 may be deposited over the dummy dielectric layer 60 and then planarized, such as by a CMP. The mask layer 64 may be deposited over the dummy gate layer 62. The dummy gate layer 62 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 62 may be deposited by physical vapor deposition (PVD), CVD, sputter deposition, or other techniques for depositing the selected material. The dummy gate layer 62 may be made of other materials that have a high etching selectivity from the etching of isolation regions, e.g., the STI regions 56 and/or the dummy dielectric layer 60. The mask layer 64 may include one or more layers of, for example, silicon nitride, silicon oxynitride, or the like. In this example, a single dummy gate layer 62 and a single mask layer 64 are formed across the n-type region 50N and the p-type region 50P. It is noted that the dummy dielectric layer 60 is shown covering only the fins 52 for illustrative purposes only. In some embodiments, the dummy dielectric layer 60 may be deposited such that the dummy dielectric layer 60 covers the STI regions 56 (e.g., the insulation material 54 and the oxide liner 132), extending over the STI regions and between the dummy gate layer 62 and the STI regions 56.

FIGS. 10A through 18B illustrate various additional steps in the manufacturing of embodiment devices. FIGS. 10A through 18B illustrate features in either of the n-type region 50N and the p-type region 50P. For example, the structures illustrated in FIGS. 10A through 18B may be applicable to both the n-type region 50N and the p-type region 50P. Differences (if any) in the structures of the n-type region 50N and the p-type region 50P are described in the text accompanying each figure.

In FIGS. 10A and 10B, the mask layer 64 (see FIG. 9) may be patterned using acceptable photolithography and etching techniques to form masks 74. The pattern of the masks 74 then may be transferred to the dummy gate layer 62. In some embodiments (not illustrated), the pattern of the masks 74 may also be transferred to the dummy dielectric layer 60 by an acceptable etching technique to form dummy gates 72. The dummy gates 72 cover respective channel regions 58 of the fins 52. The pattern of the masks 74 may be used to physically separate each of the dummy gates 72 from adjacent dummy gates. The dummy gates 72 may also have a lengthwise direction substantially perpendicular to the lengthwise direction of respective epitaxial fins 52.

Further in FIGS. 10A and 10B, gate seal spacers 80 can be formed on exposed surfaces of the dummy gates 72, the masks 74, and/or the fins 52. A thermal oxidation or a deposition followed by an anisotropic etch may form the gate seal spacers 80. The gate seal spacers 80 may be formed of silicon oxide, silicon nitride, silicon oxynitride, or the like.

After the formation of the gate seal spacers 80, implants for lightly doped source/drain (LDD) regions (not explicitly illustrated) may be performed. In the embodiments with different device types, similar to the implants discussed above in FIG. 8A, a mask, such as a photoresist, may be formed over the n-type region 50N, while exposing the p-type region 50P, and appropriate type (e.g., p-type) impurities may be implanted into the exposed fins 52 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 52 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities of from about 10¹⁵ cm⁻³ to about 10¹⁹ cm⁻³. An anneal may be used to repair implant damage and to activate the implanted impurities.

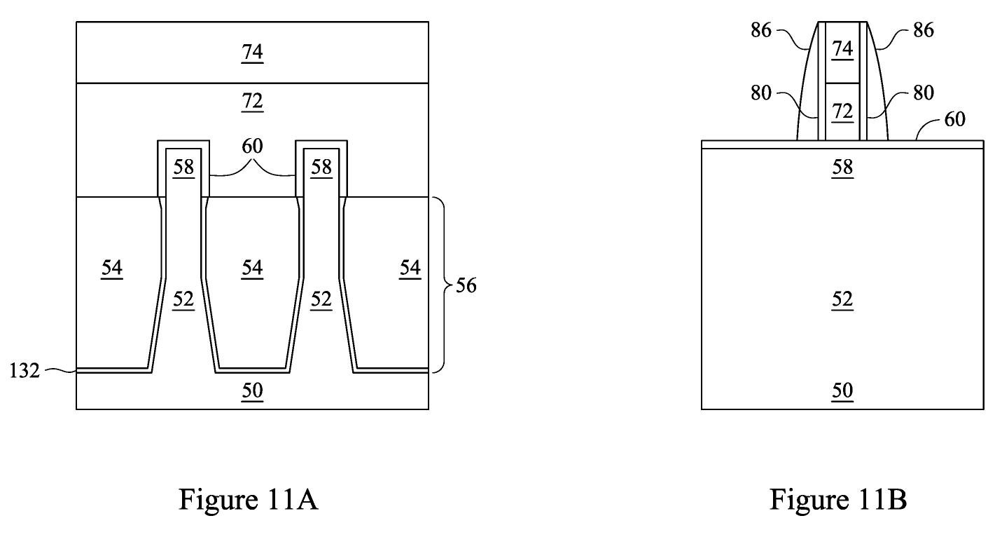

In FIGS. 11A and 11B, gate spacers 86 are formed on the gate seal spacers 80 along sidewalls of the dummy gates 72 and the masks 74. The gate spacers 86 may be formed by conformally depositing an insulating material and subsequently anisotropic ally etching the insulating material. The insulating material of the gate spacers 86 may be silicon oxide, silicon nitride, silicon oxynitride, silicon carbonitrides, a combination thereof, or the like.

It is noted that the above disclosure generally describes a process of forming spacers and LDD regions. Other processes and sequences may be used. For example, fewer or additional spacers may be utilized, different sequence of steps may be utilized (e.g., the gate seal spacers 80 may not be etched prior to forming the gate spacers 86), yielding “L-shaped” gate seal spacers, spacers may be formed and removed, and/or the like. Furthermore, the n-type and p-type devices may be formed using a different structures and steps. For example, LDD regions for n-type devices may be formed prior to forming the gate seal spacers 80 while the LDD regions for p-type devices may be formed after forming the gate seal spacers 80.

In FIGS. 12A and 12B epitaxial source/drain regions 82 are formed in the fins 52. The epitaxial source/drain regions 82 are formed in the fins 52 such that each dummy gate 72 is disposed between respective neighboring pairs of the epitaxial source/drain regions 82. In some embodiments the epitaxial source/drain regions 82 may extend into, and may also penetrate through, the fins 52. In some embodiments, the gate spacers 86 are used to separate the epitaxial source/drain regions 82 from the dummy gates 72 by an appropriate lateral distance so that the epitaxial source/drain regions 82 do not short out subsequently formed gates of the resulting FinFETs. A material of the epitaxial source/drain regions 82 may be selected to exert stress in the respective channel regions 58, thereby improving performance.

The epitaxial source/drain regions 82 in the n-type region 50N may be formed by masking the p-type region 50P and etching source/drain regions of the fins 52 in the n-type region 50N to form recesses in the fins 52. Then, the epitaxial source/drain regions 82 in the n-type region 50N are epitaxially grown in the recesses. The epitaxial source/drain regions 82 may include any acceptable material, such as appropriate for n-type FinFETs. For example, if the fin 52 is silicon, the epitaxial source/drain regions 82 in the n-type region 50N may include materials exerting a tensile strain in the channel region 58, such as silicon, silicon carbide, phosphorous doped silicon carbide, silicon phosphide, or the like. The epitaxial source/drain regions 82 in the n-type region 50N may have surfaces raised from respective surfaces of the fins 52 and may have facets.

The epitaxial source/drain regions 82 in the p-type region 50P may be formed by masking the n-type region 50N and etching source/drain regions of the fins 52 in the p-type region 50P to form recesses in the fins 52. Then, the epitaxial source/drain regions 82 in the p-type region 50P are epitaxially grown in the recesses. The epitaxial source/drain regions 82 may include any acceptable material, such as appropriate for p-type FinFETs. For example, if the fin 52 is silicon, the epitaxial source/drain regions 82 in the p-type region 50P may comprise materials exerting a compressive strain in the channel region 58, such as silicon-germanium, boron doped silicon-germanium, germanium, germanium tin, or the like. The epitaxial source/drain regions 82 in the p-type region 50P may have surfaces raised from respective surfaces of the fins 52 and may have facets.

The epitaxial source/drain regions 82 and/or the fins 52 may be implanted with dopants to form source/drain regions, similar to the process previously discussed for forming lightly doped source/drain regions, followed by an anneal. The source/drain regions may have an impurity concentration of between about 10¹⁹ cm⁻³ and about 10²¹ cm⁻³. The n-type and/or p-type impurities for source/drain regions may be any of the impurities previously discussed. In some embodiments, the epitaxial source/drain regions 82 may be in situ doped during growth.

As a result of the epitaxy processes used to form the epitaxial source/drain regions 82 in the n-type region 50N and the p-type region 50P, upper surfaces of the epitaxial source/drain regions have facets which expand laterally outward beyond sidewalls of the fins 52. In some embodiments, these facets cause adjacent source/drain regions 82 of a same FinFET to merge as illustrated by FIG. 12C. In other embodiments, adjacent source/drain regions 82 remain separated after the epitaxy process is completed as illustrated by FIG. 12D. In the embodiments illustrated in FIGS. 12C and 12D, gate spacers 86 are formed covering a portion of the sidewalls of the fins 52 that extend above the STI regions 56 thereby blocking the epitaxial growth. In some other embodiments, the spacer etch used to form the gate spacers 86 may be adjusted to remove the spacer material to allow the epitaxially grown region to extend to the surface of the STI region 56.

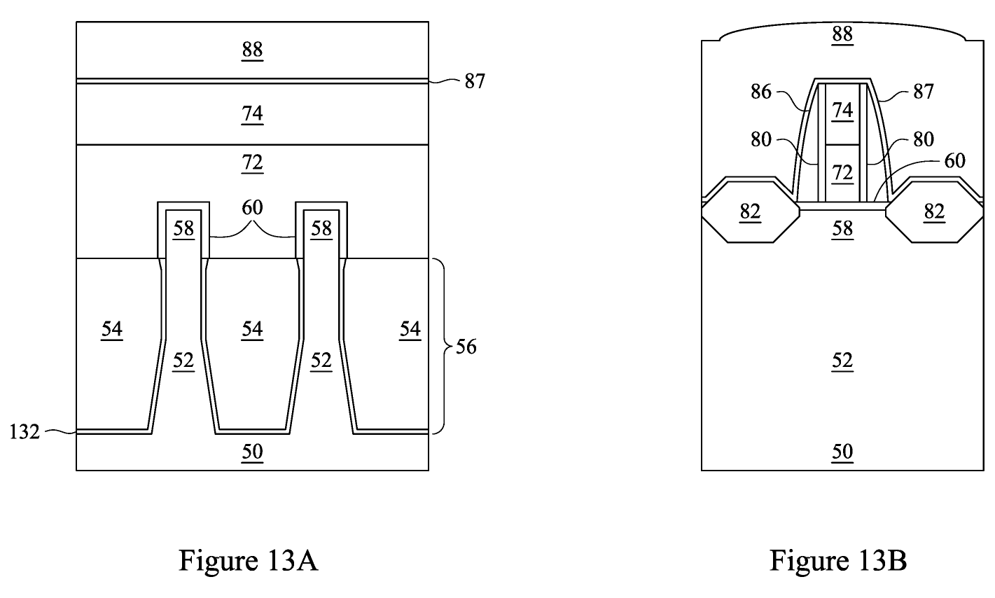

In FIGS. 13A and 13B, a first interlayer dielectric (ILD) 88 is deposited over the structure illustrated in FIGS. 12A and 12B. The first ILD 88 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stops layer (CESL) 87 is disposed between the first ILD 88 and the epitaxial source/drain regions 82, the masks 74, and the gate spacers 86. The CESL 87 may comprise a dielectric material, such as, silicon nitride, silicon oxide, silicon oxynitride, or the like, having a lower etch rate than the material of the overlying first ILD 88.

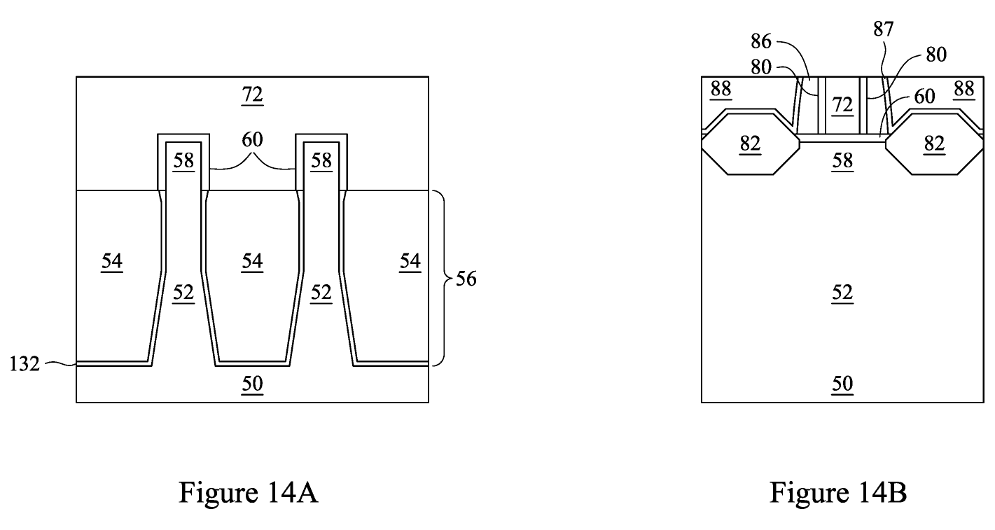

In FIGS. 14A and 14B, a planarization process, such as a CMP, may be performed to level the top surface of the first ILD 88 with the top surfaces of the dummy gates 72 or the masks 74. The planarization process may also remove the masks 74 on the dummy gates 72, and portions of the gate seal spacers 80 and the gate spacers 86 along sidewalls of the masks 74. After the planarization process, top surfaces of the dummy gates 72, the gate seal spacers 80, the gate spacers 86, and the first ILD 88 are level. Accordingly, the top surfaces of the dummy gates 72 are exposed through the first ILD 88. In some embodiments, the masks 74 may remain, in which case the planarization process levels the top surface of the first ILD 88 with the top surfaces of the top surface of the masks 74.

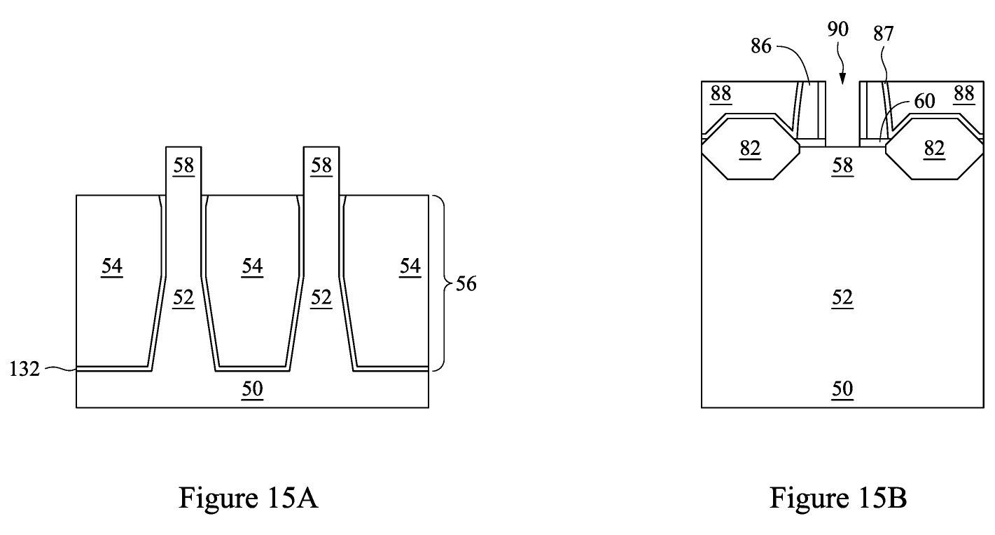

In FIGS. 15A and 15B, the dummy gates 72, and the masks 74 if present, are removed in an etching step(s), so that recesses 90 are formed. Portions of the dummy dielectric layer 60 in the recesses 90 may also be removed. In some embodiments, only the dummy gates 72 are removed and the dummy dielectric layer 60 remains and is exposed by the recesses 90. In some embodiments, the dummy dielectric layer 60 is removed from recesses 90 in a first region of a die (e.g., a core logic region) and remains in recesses 90 in a second region of the die (e.g., an input/output region). In some embodiments, the dummy gates 72 are removed by an anisotropic dry etch process. For example, the etching process may include a dry etch process using reaction gas(es) that selectively etch the dummy gates 72 with little or no etching of the first ILD 88 or the gate spacers 86. Each recess 90 exposes and/or overlies a channel region 58 of a respective fin 52. Each channel region 58 is disposed between neighboring pairs of the epitaxial source/drain regions 82. During the removal, the dummy dielectric layer 60 may be used as an etch stop layer when the dummy gates 72 are etched. The dummy dielectric layer 60 may then be optionally removed after the removal of the dummy gates 72.

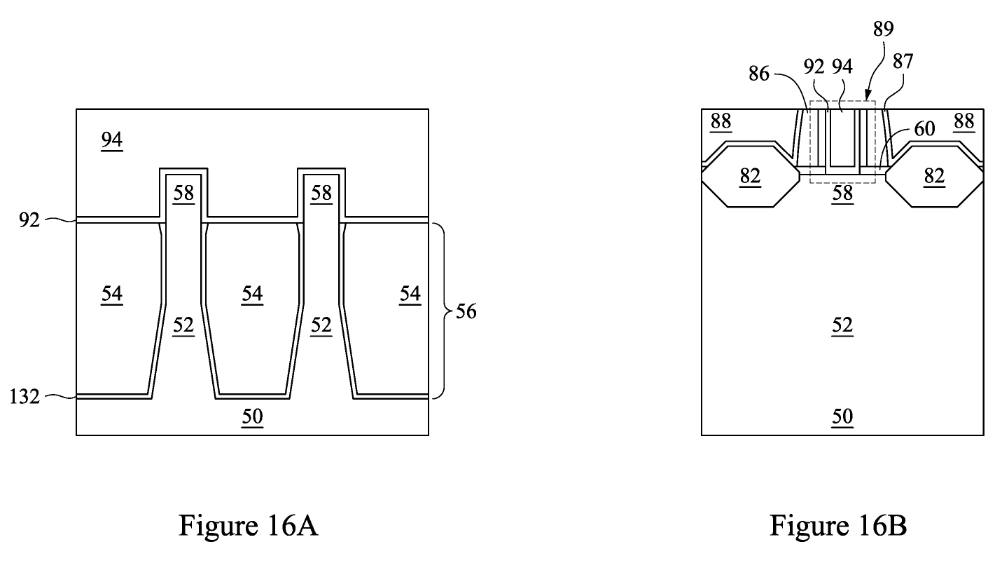

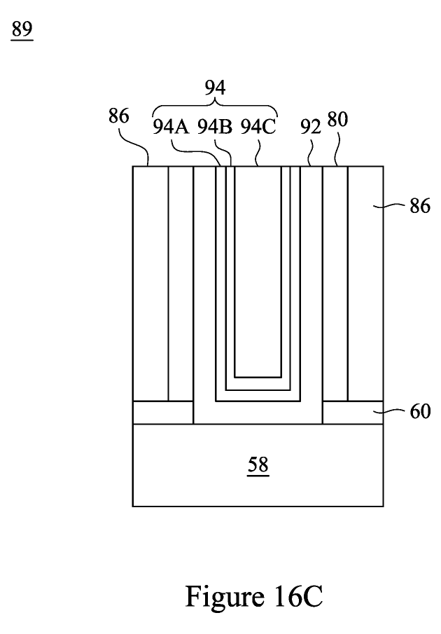

In FIGS. 16A and 16B, gate dielectric layers 92 and gate electrodes 94 are formed for replacement gates. FIG. 16C illustrates a detailed view of region 89 of FIG. 16B. Gate dielectric layers 92 one or more layers deposited in the recesses 90, such as on the top surfaces and the sidewalls of the fins 52 and on sidewalls of the gate seal spacers 80 / gate spacers 86. The gate dielectric layers 92 may also be formed on the top surface of the first ILD 88. In some embodiments, the gate dielectric layers 92 comprise one or more dielectric layers, such as one or more layers of silicon oxide, silicon nitride, metal oxide, metal silicate, or the like. For example, in some embodiments, the gate dielectric layers 92 include an interfacial layer of silicon oxide formed by thermal or chemical oxidation and an overlying high-k dielectric material, such as a metal oxide or a silicate of hafnium, aluminum, zirconium, lanthanum, manganese, barium, titanium, lead, and combinations thereof. The gate dielectric layers 92 may include a dielectric layer having a k value greater than about 7.0. The formation methods of the gate dielectric layers 92 may include Molecular-Beam Deposition (MBD), ALD, PECVD, and the like. In embodiments where portions of the dummy dielectric layer 60 remains in the recesses 90, the gate dielectric layers 92 include a material of the dummy dielectric layer 60 (e.g., SiO₂).

The gate electrodes 94 are deposited over the gate dielectric layers 92, respectively, and fill the remaining portions of the recesses 90. The gate electrodes 94 may include a metal-containing material such as titanium nitride, titanium oxide, tantalum nitride, tantalum carbide, cobalt, ruthenium, aluminum, tungsten, combinations thereof, or multi-layers thereof. For example, although a single layer gate electrode 94 is illustrated in FIG. 16B, the gate electrode 94 may comprise any number of liner layers 94A, any number of work function tuning layers 94B, and a fill material 94C as illustrated by FIG. 16C. After the filling of the recesses 90, a planarization process, such as a CMP, may be performed to remove the excess portions of the gate dielectric layers 92 and the material of the gate electrodes 94, which excess portions are over the top surface of the first ILD 88. The remaining portions of material of the gate electrodes 94 and the gate dielectric layers 92 thus form replacement gates of the resulting FinFETs. The gate electrodes 94 and the gate dielectric layers 92 may be collectively referred to as a “gate stack.” The gate and the gate stacks may extend along sidewalls of a channel region 58 of the fins 52.

The formation of the gate dielectric layers 92 in the n-type region 50N and the p-type region 50P may occur simultaneously such that the gate dielectric layers 92 in each region are formed from the same materials, and the formation of the gate electrodes 94 may occur simultaneously such that the gate electrodes 94 in each region are formed from the same materials. In some embodiments, the gate dielectric layers 92 in each region may be formed by distinct processes, such that the gate dielectric layers 92 may be different materials, and/or the gate electrodes 94 in each region may be formed by distinct processes, such that the gate electrodes 94 may be different materials. Various masking steps may be used to mask and expose appropriate regions when using distinct processes.

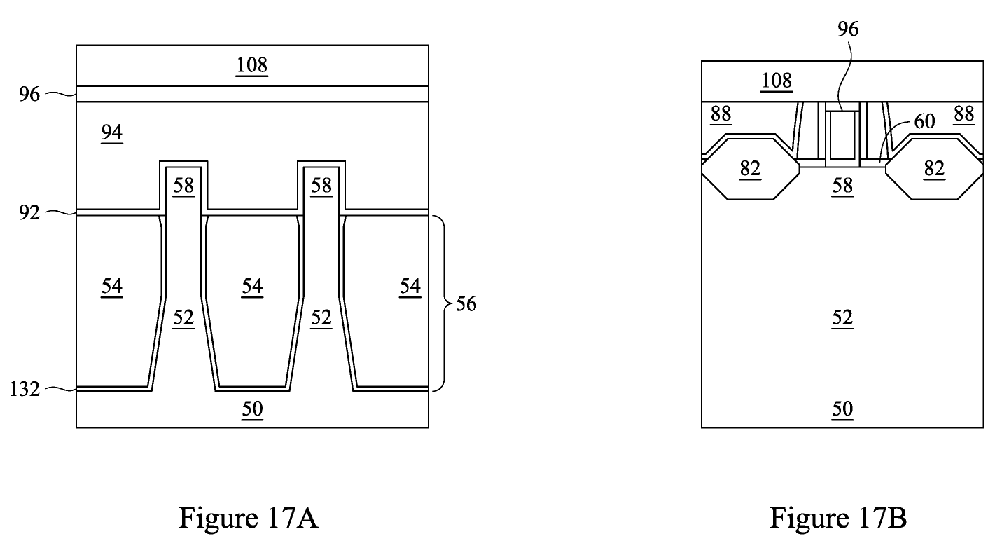

In FIGS. 17A and 17B, a gate mask 96 is formed over the gate stack (including a gate dielectric layer 92 and a corresponding gate electrode 94), and the gate mask may be disposed between opposing portions of the gate spacers 86. In some embodiments, forming the gate mask 96 includes recessing the gate stack so that a recess is formed directly over the gate stack and between opposing portions of gate spacers 86. A gate mask 96 comprising one or more layers of dielectric material, such as silicon nitride, silicon oxynitride, or the like, is filled in the recess, followed by a planarization process to remove excess portions of the dielectric material extending over the first ILD 88. The gate mask 96 is optional and may be omitted in some embodiments. In such embodiments, the gate stack may remain level with top surfaces of the first ILD 88.

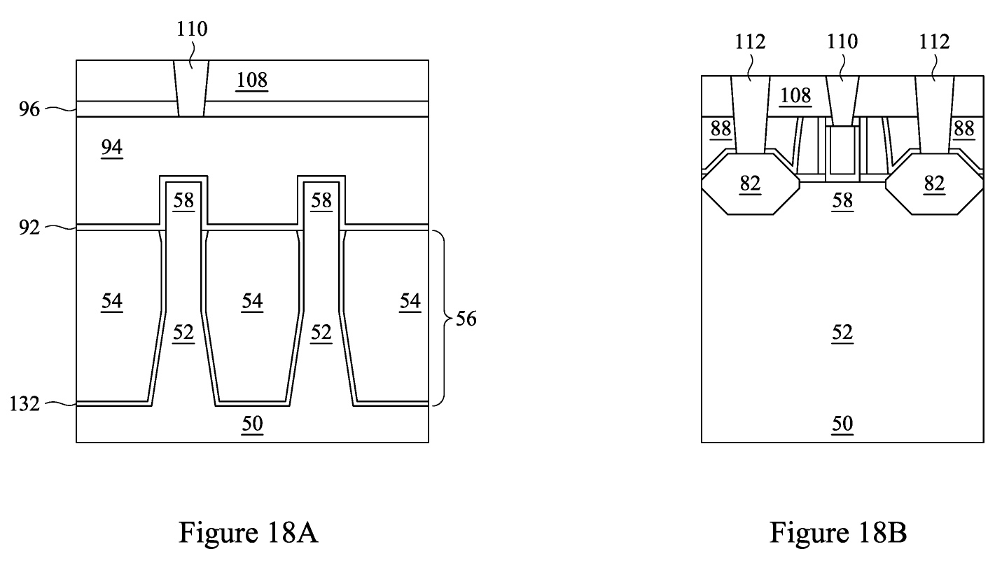

As also illustrated in FIGS. 17A and 17B, a second ILD 108 is deposited over the first ILD 88. In some embodiments, the second ILD 108 is a flowable film formed by a flowable CVD method. In some embodiments, the second ILD 108 is formed of a dielectric material such as PSG, BSG, BPSG, USG, or the like, and may be deposited by any suitable method, such as CVD and PECVD. The subsequently formed gate contacts 110 (FIGS. 18A and 18B) penetrate through the second ILD 108 and the gate mask 96 (if present) to contact the top surface of the recessed gate electrode 94.

In FIGS. 18A and 18B, gate contacts 110 and source/drain contacts 112 are formed through the second ILD 108 and the first ILD 88 in accordance with some embodiments. Openings for the source/drain contacts 112 are formed through the first and second ILDs 88 and 108, and openings for the gate contact 110 are formed through the second ILD 108 and the gate mask 96 (if present). The openings may be formed using acceptable photolithography and etching techniques. A liner (not shown), such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 108. The remaining liner and conductive material form the source/drain contacts 112 and gate contacts 110 in the openings. An anneal process may be performed to form a silicide at the interface between the epitaxial source/drain regions 82 and the source/drain contacts 112. The source/drain contacts 112 are physically and electrically coupled to the epitaxial source/drain regions 82, and the gate contacts 110 are physically and electrically coupled to the gate electrodes 106. The source/drain contacts 112 and gate contacts 110 may be formed in different processes or may be formed in the same process. Although shown as being formed in the same cross-sections, it should be appreciated that each of the source/drain contacts 112 and gate contacts 110 may be formed in different cross-sections, which may avoid shorting of the contacts.

Advantages may be achieved. The processes used for depositing and treating the oxide liner 132 improve the efficiency of subsequent steps, such as depositing the insulation material 54 in the recesses 130 between neighboring fins 52. In particular, after conformally depositing the oxide liner 132, the upper portions of the oxide liner 132 on neighboring fins may be thick enough to partially close the mouth of the recess 130. By performing the post-deposition treatment to etch those upper portions of the oxide liner 132, the mouth of the recess 130 is widened to provide greater space for depositing the insulation material 54 to fill the remainder of the recess 130. As a result, the insulation material 54 is free of voids, and the STI region 56 is formed at a higher yield. The embodiments may increase the efficiency of fabricating the semiconductor devices, reduce costs, and improve the performance of the semiconductor devices.

The disclosed FinFET embodiments could also be applied to nanostructure devices such as nanostructure (e.g., nanosheet, nanowire, gate-all-around, or the like) field effect transistors (NSFETs). In an NSFET embodiment, the fins are replaced by nanostructures formed by patterning a stack of alternating layers of channel layers and sacrificial layers. Dummy gate stacks and source/drain regions are formed in a manner similar to the above-described embodiments. After the dummy gate stacks are removed, the sacrificial layers can be partially or fully removed in channel regions. The replacement gate structures are formed in a manner similar to the above-described embodiments, the replacement gate structures may partially or completely fill openings left by removing the sacrificial layers, and the replacement gate structures may partially or completely surround the channel layers in the channel regions of the NSFET devices. ILDs and contacts to the replacement gate structures and the source/drain regions may be formed in a manner similar to the above-described embodiments. A nanostructure device can be formed as disclosed in U.S. Patent No. 9,647,071, which is incorporated herein by reference in its entirety.

In an embodiment, a method includes: forming a first fin and a second fin over a semiconductor substrate; forming an isolation region between the first fin and the second fin, forming the isolation region comprising: depositing an oxide liner along the first fin, the second fin, and the semiconductor substrate, the oxide liner comprising a first upper portion and a first lower portion along the first fin, the first lower portion being between the first upper portion and the semiconductor substrate; thinning the oxide liner; depositing an insulation material over the oxide liner; and recessing the insulation material; and forming a gate structure over the first fin, the second fin, and the isolation region. In another embodiment, thinning the oxide liner comprises performing a post-deposition plasma process on the oxide liner. In another embodiment, the post-deposition plasma process comprises an anisotropic etch. In another embodiment, before thinning the oxide liner, the first upper portion of the oxide liner overhangs the first lower portion of the oxide liner by a first distance, wherein after thinning the oxide liner, the first upper portion of the oxide liner overhangs the first lower portion of the oxide liner by a second distance, and wherein the first distance is greater than the second distance. In another embodiment, thinning the oxide liner comprises thinning the first upper portion by a greater amount than thinning the first lower portion. In another embodiment, the oxide liner further comprises a second upper portion and a second lower portion along the second fin, wherein thinning the oxide liner comprises increasing a first lateral distance between the first upper portion and the second upper portion of the oxide liner. In another embodiment, thinning the oxide liner comprises increasing a second lateral distance between the first lower portion and the second lower portion of the oxide liner, and wherein increasing the first lateral distance is by a greater amount than increasing the second lateral distance.

In an embodiment, a method includes: forming a first semiconductor fin over a substrate; depositing an oxide layer over the first semiconductor fin to form a first combined fin comprising a first portion of the oxide layer and the first semiconductor fin, in a cross-section the first combined fin having an upper region and a middle region, the upper region being at a top of the first combined fin, the middle region being midway between the upper region and the substrate, a first upper width of the upper region being greater than a first middle width of the middle region; performing a plasma process on the oxide layer, wherein after performing the plasma process: a second upper width of the upper region is less than the first upper width; and a second middle width of the middle region is less than the first middle width; depositing an insulation material over the first combined fin; and recessing the insulation material and the oxide layer to be below a top surface of the first semiconductor fin. In another embodiment, depositing the oxide layer comprises an atomic layer deposition, wherein the atomic layer deposition comprises flowing a first precursor and a plasma of a second precursor. In another embodiment, the first precursor is a silicon precursor, and wherein the second precursor is an oxygen precursor. In another embodiment, the plasma process comprises flowing the plasma of the second precursor. In another embodiment, the atomic layer deposition comprises flowing an ambient material and a plasma of the ambient material, and wherein the plasma process comprises flowing the plasma of the ambient material. In another embodiment, the atomic layer deposition comprises a plasma generator set to a first power, wherein the plasma process comprises the plasma generator set to a second power, and wherein the second power is more than ten times greater than the first power. In another embodiment, the method further includes: forming a second semiconductor fin over the substrate, a recess being between the first semiconductor fin and the second semiconductor fin; and depositing the oxide layer over the second semiconductor fin to form a second combined fin comprising a second portion of the oxide layer and the second semiconductor fin, wherein before performing the plasma process the first combined fin and the second combined fin are separated by a first shortest lateral distance, wherein after performing the plasma process the first combined fin and the second combined fin are separated from one another by a second shortest lateral distance, and wherein the second shortest lateral distance is greater than the first shortest lateral distance. In another embodiment, performing the plasma process densifies the oxide layer.

In an embodiment, a semiconductor device includes: a first fin and a second fin over a substrate; an isolation region over the substrate and between the first fin and the second fin, the isolation region comprising: an oxide liner extending continuously from a first upper region of the first fin to a second upper region of the second fin, the oxide liner having a first thickness adjacent to the first upper region, a second thickness adjacent to the second upper region, and a third thickness adjacent to the substrate, the third thickness being less than the first thickness; and an insulation material within a U-shape of the oxide liner; a gate dielectric extending continuously from the first upper region to the second upper region; and a gate electrode over the gate dielectric and between the first upper region and the second upper region. In another embodiment, the oxide liner has a fourth thickness adjacent to a first middle region of the first fin, wherein the first thickness is greater than the fourth thickness. In another embodiment, the third thickness is greater than the second thickness. In another embodiment, the gate dielectric is in physical contact with the oxide liner and the insulation material. In another embodiment, the insulation material is free of voids.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first fin and a second fin over a semiconductor substrate;
an isolation region between the first fin and the second fin, the first fin protruding above a top surface of the isolation region, the isolation region comprising:
an oxide liner along the first fin, the second fin, and the semiconductor substrate; and
an insulation material over the oxide liner, the insulation material being free of voids; and
a gate structure over the first fin, the second fin, and the isolation region,
wherein the oxide liner comprises an upper portion along an upper region of the first fin and a middle portion along a middle region of the first fin, a first thickness of the upper portion being greater than a second thickness of the middle portion.

2. The semiconductor device of claim 2 wherein the oxide liner further comprises a lower portion along a lower region of the first fin having a third thickness and a substrate portion along the semiconductor substrate having a fourth thickness, the first thickness of the upper portion being greater than the fourth thickness of the substrate portion.

3. The semiconductor device of claim 2, wherein the third thickness of the lower portion is greater than the fourth thickness of the substrate portion.

4. The semiconductor device of claim 2, wherein the second thickness of the middle portion is greater than the fourth thickness of the substrate portion.

5. The semiconductor device of claim 1, wherein the oxide liner comprises silicon oxide or silicon oxynitride.

6. The semiconductor device of claim 1, wherein the oxide liner has an average thickness from 18 Å to 20 Å.

7. The semiconductor device of claim 1, wherein the gate structure comprises a gate dielectric layer along sidewalls and over a top surface of the first fin, and a gate electrode over the gate dielectric layer.

8. The semiconductor device of claim 1, wherein a part of the upper region of the first fin protruding above the top surface of the isolation region is covered by the upper portion of the oxide liner.

9. A method comprising:
forming a first fin and a second fin over a substrate, a recess being between the first fin and the second fin;
forming an oxide liner over the first fin, the second fin, and the substrate by an atomic layer deposition process in a reaction chamber, the atomic layer deposition process flowing an oxygen precursor and an ambient material into the reaction chamber, the atomic layer deposition process comprising a plurality of cycles, a first cycle of the plurality of cycles comprising:
flowing a silicon precursor into the reaction chamber to deposit silicon-containing molecules; and
activating a plasma generator to deposit oxygen-containing molecules over the silicon-containing molecules;
after forming the oxide liner, performing a post-deposition treatment on the oxide liner in the reaction chamber, the post-deposition treatment flowing the oxygen precursor and the ambient material into the reaction chamber and activating the plasma generator, the post-deposition treatment densifying the oxide liner, removing an impurity from the oxide liner, and thinning an upper portion of the oxide liner to widen a mouth of the recess;
depositing an insulation material over the oxide liner and in the recess; and
recessing the insulation material and the oxide liner below a top surface of the first fin and a top surface of the second fin.

10. The method of claim 9, wherein the impurity comprises nitrogen, carbon, or a combination thereof.

11. The method of claim 9, wherein the post-deposition treatment thins the upper portion of the oxide liner by a greater amount than a middle portion of the oxide liner along a middle region of the first fin.

12. The method of claim 9, wherein before the post-deposition treatment the upper portion of the oxide liner overhangs a middle portion of the oxide liner by a first distance, wherein after the post-deposition treatment the upper portion of the oxide liner overhangs the middle portion by a second distance, and wherein the first distance is greater than the second distance.

13. The method of claim 9, wherein activating the plasma generator during the atomic layer deposition process comprises setting the plasma generator to a first power, wherein activating the plasma generator during the post-deposition treatment comprises setting the plasma generator to a second power, and wherein the second power is greater than or equal to 11 times the first power.

14. The method of claim 9, wherein the silicon precursor comprises silane, the oxygen precursor comprises oxygen or carbon dioxide, and the ambient material comprises argon or helium.

15. The method of claim 9, wherein depositing the insulation material comprises a flowable chemical vapor deposition process, and wherein the insulation material is free of voids.

16. A method comprising:
forming a liner in a recess having a high aspect ratio, an upper portion of the liner overhanging a lower portion of the liner such that the upper portion partially closes a mouth of the recess;
performing a plasma treatment on the liner, the plasma treatment thinning the upper portion of the liner by a greater amount than the lower portion of the liner to widen the mouth of the recess; and
after performing the plasma treatment, depositing a gap-fill material in the recess, the gap-fill material being free of voids.

17. The method of claim 16, wherein forming the liner comprises an atomic layer deposition process, and wherein performing the plasma treatment comprises a continuation of the atomic layer deposition process within a reaction chamber.

18. The method of claim 16, wherein performing the plasma treatment comprises an anisotropic etch of the liner.

19. The method of claim 16, wherein performing the plasma treatment densifies the liner and removes an impurity from the liner.

20. The method of claim 16, wherein the liner comprises silicon oxide or silicon oxynitride, and wherein the recess is between a first fin and a second fin over a semiconductor substrate.
